(19) United States
(12) Patent Application Publication
(10) Pub. No.: US 2009/0321765 A1
(43) Pub. Date: Dec. 31, 2009

(54) LIGHT EMITTING DIODE

(75) Inventor: Chia-Shou Chang, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: Foxconn Technology Co., Ltd., Tu-Cheng (TW)

(21) Appl. No.: 12/412,372

(22) Filed: Mar. 27, 2009

(30) Foreign Application Priority Data
Jun. 25, 2008 (CN) 200810068102.1

(51) Int. Cl. H01L 33/00

(52) U.S. Cl. 257/98; 257/99; 257/E33.068; 257/E33.066

(57) ABSTRACT

An LED includes an LED die forming an emitting surface for emitting light generated thereby and a packaging layer encapsulating the LED die. The packaging layer includes an end surface facing the emitting surface of the LED die, and a lateral surface extending downwardly from an outer periphery of the end surface along an axial direction of the packaging layer. The end surface forms a convex portion confronting the LED die and an emitting portion surrounding the convex portion. Light of the LED die traveling to the convex portion is reflected to the lateral surface, and then is reflected to the emitting portion, and finally travels through the emitting portion to an outside.

### BACKGROUND

1. Technical Field

The disclosure generally relates to light emitting diodes, and particularly to a light emitting diode with uniform light distribution.

2. Description of Related Art

In recent years, light emitting diodes (LEDs) have been widely used in illumination. However, the LED is a point light source, and an emitting surface thereof is usually hemispherical. An intensity of a light field of the LED decreases gradually and outwardly along a radial direction thereof, i.e., the intensity of the light field of the LED is uneven, being strong at a center of the light field and being weak at a periphery of the light field of the LED.

For the foregoing reasons, therefore, there is a need in the art for an LED which overcomes the limitations described.

### BRIEF DESCRIPTION OF THE DRAWINGS

FIG. 1 is an isometric, assembled view of a light emitting diode according to an exemplary embodiment.

FIG. 2 is a cross sectional view of the light emitting diode taken along line II-II of FIG. 1.

FIG. 3 is a view similar to FIG. 2, showing an alternative embodiment of the light emitting diode.

### DETAILED DESCRIPTION

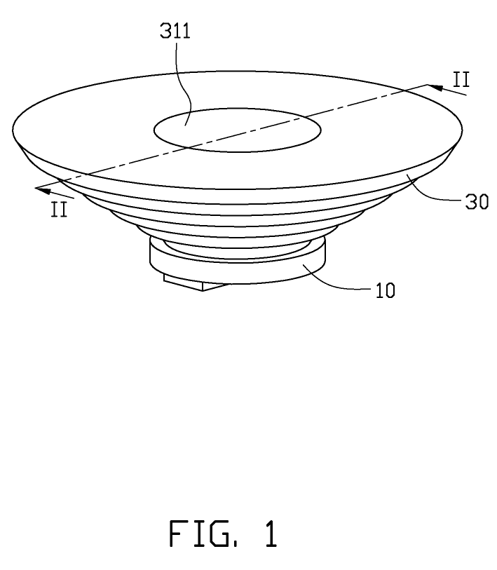

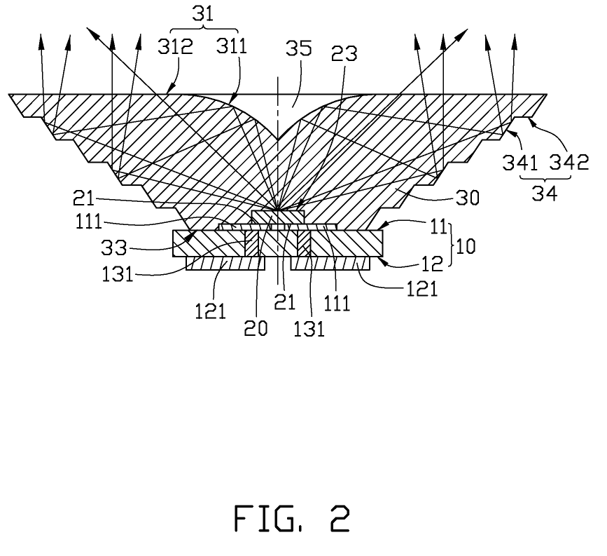

Referring to FIGS. 1 and 2, a light emitting diode (LED) according to an exemplary embodiment includes a substrate 10, an LED die 20, and a packaging layer 30.

The substrate 10 is disc-shaped, and includes an upper side 11 and a lower side 12 opposite to the upper side 11. The substrate 10 defines a pair of through holes (not labeled) near a center thereof. The pair of through holes extend through the substrate 10 vertically from the upper side 11 to the lower side 12. The pair of through holes are spaced from each other. Each through hole receives one conductive pin 131 therein.

A pair of outer terminals 121 are formed on the lower side 12 of the substrate 10 corresponding to the conductive pins 131, respectively. Each outer terminal 121 is located under the corresponding conductive pin 131 and electrically connected to a bottom end of the corresponding conductive pin 131. The two outer terminals 121 are insulated and spaced from each other. Similarly, a pair of inner terminals 111 are formed on the upper side 11 of the substrate 10 corresponding to the conductive pins 131, respectively. Each inner terminal 111 is located over the corresponding conductive pin 131 and electrically connected to a top end of the corresponding conductive pin 131. The two inner terminals 111 are insulated and spaced from each other. Thus each inner terminal 111 is connected to the corresponding outer terminal 121 electrically, and is insulated from the other inner terminal 111 and the other outer terminal 121.

The LED die 20 is arranged on the upper side 11 of the substrate 10, and coaxially located on a center of the substrate 10. The LED die 20 forms an emitting surface 23 at a top side thereof, and has a pair of electrodes 21 formed at a bottom side thereof for connecting with a power source via the inner terminals 111, the conductive pins 131 and the outer terminals 121. The LED die 20 is arranged above the two inner terminals 111 with the electrodes 21 thereof connecting to the inner terminals 111 of the substrate 10, respectively. Thus the electrodes 21 of the LED die 20 are respectively electrically connected to the outer terminals 121 through the inner terminals 111 and the conductive pins 131.

The packaging layer 30 is coupled to the upper side 11 of the substrate 10 to encapsulate the LED die 20 therebetween. The packaging layer 30 is made of transparent materials, such as resin, acryl, silica gel or glass. The packaging layer 30 is substantially conversely truncated conical, and has a cross section decreasing downwardly and gradually. The packaging layer 30 has a bottom surface 33 attached to the upper side 11 of the substrate 10, a top surface 31 opposite to the bottom surface 33 and a lateral surface 34 interconnecting the top surface 31 and the bottom surface 33. In this embodiment, the bottom surface 33 is smaller than the upper side 11 of the substrate 10. A cavity (not labeled) depresses inwardly from a central portion of the bottom surface 33 into the packaging layer 30 for accommodating the LED die 20 and the inner terminals 111 therein.

The lateral surface 34 expands upwardly from an outer periphery of the bottom surface 33. The lateral surface 34 is ladder-shaped, and includes a plurality of shoulders 342 and a plurality of necks 341 arranged in an alternating fashion along an axial direction of the packaging layer 30. Each shoulder 342 is substantially horizontal and annular, and each neck 341 is substantially cylindrical-shaped and expands upwardly. A bottom neck 341 of the lateral surface 34 connects to the bottom surface 33 of the packaging layer 30, and a top neck 341 of the lateral surface 34 connects to the top surface 31 of the packaging layer 30. Each shoulder 342 interconnects a top end of an adjacent lower neck 341 and a bottom end of an adjacent upper neck 341. Thus the lateral surface 34 of the packaging layer 30 constructs a total reflecting surface for effectively reflecting light of the LED die 20 to the top surface 31. For enhancing reflection effect of the lateral surface 34, a layer of reflecting material, such as mercury is coated on the lateral surface 34. Thus no light can pass through the lateral surface 34 of the packaging layer 30 to an outside; almost all of the light of the LED die 20 can be reflected towards the top surface 31 of the packaging layer 30.

The top surface 31 of the packaging layer 30 faces the emitting surface 23 of the LED die 20 for emitting light of the LED die 20. A concave 35 is defined at a central portion of the top surface 31 and located over the LED die 20. Thus the top surface 31 of the packaging layer 30 forms a convex portion 311 at a bottom of the concave 35 and over the LED die 20, and an emitting portion 312 around the convex portion 311. The concave 35 has a depth decreases radially and outwardly from a center of the top surface 31 of the packaging layer 30. In other words, the convex portion 311 has a height increasing radially and outwardly from the center of the top surface 31. In this embodiment, the convex portion 311 is for reflecting as much as possible light of the LED die 20 to the lateral surface 34 of the packaging layer 30. The emitting portion 312 extends radially and outwardly from an outer periphery of the convex portion 311. The emitting portion 312 of the top surface 31 is substantially horizontal and annular.

During operation, the two outer terminals 121 are connected to the power source for supplying current to the LED die 20 to cause it to emit light. Part of the light of the LED die 20 which travels substantially vertically to the convex portion 311 of the top surface 31 of the packaging layer 30 is almost reflected to the lateral surface 34 of the packaging layer 30 due to the convex configuration of the convex portion 311; then, the part of the light is reflected to the emitting portion 312 of the top surface 31 by the total reflecting lateral surface 34 of the packaging layer 30, and finally travels through the emitting portion 312 to the outside for lighting. Furthermore, another part of the light of the LED die 20 travels to the emitting portion 312 of the top surface 31 directly, and then travels through the emitting portion 312 to the outside. In addition, still another part of the light of the LED die 20 travels to the lateral surface 34 and then is reflected to the emitting portion 312, and finally travels through the emitting portion 312 to the outside. Thus a majority of the light travels through the emitting portion 312 of the top surface 31 to the outside; an intensity of the light field of the present LED at a periphery of the LED die 20 is enhanced, and thus the distribution of the light field of the LED is more even.

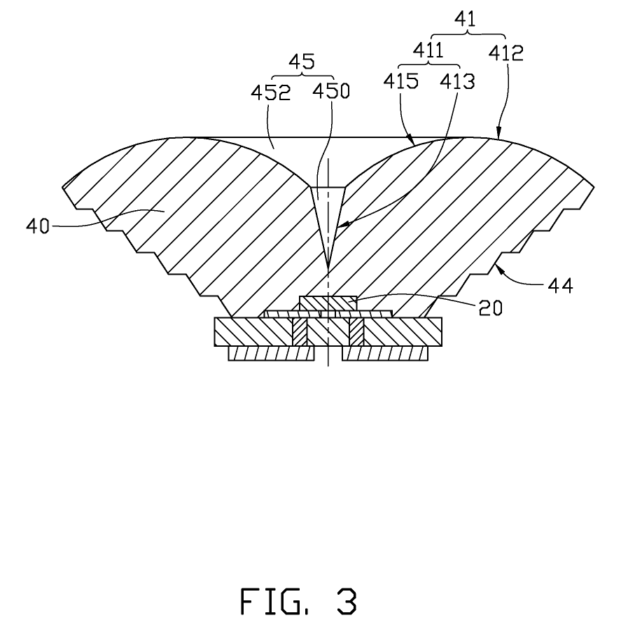

FIG. 3 shows the LED according to an alternative embodiment including a packaging layer 40 encapsulating the LED chip 20 therein. The packaging layer 40 includes a top surface 41 facing the LED chip 20 and a ladder-shaped lateral surface 44 having a diameter gradually decreasing from an outer periphery of the top surface 41 along a downward direction. The difference between this embodiment and the first embodiment resides in the top surface 41 of the packaging layer 40. In this embodiment, the packaging layer 40 defines a concave 45 in a central portion thereof, and thus forms a convex portion 411 and an emitting portion 412 surrounding the convex portion 411. The concave 45 includes an upper portion 450 and a lower portion 452. The lower portion 452 is an inverted cone. A central axis of the lower portion 452 of the concave 45 is collinear with the central axis of the packaging layer 40. The upper portion 450 of the concave 45 expands radially and upwardly from a top end of the lower portion 452. Thus, the convex portion 411 of the packaging layer 40 includes an inverted cone-shaped surface 413 and a convex surface 415 extending outwardly and upwardly from the top of the inverted cone-shaped surface 413. The emitting portion 412 is convex, and extending outwardly and downwardly from an outer periphery of the convex surface 415 of the convex portion 411. In other words, a height of the emitting portion 412 radially and outwardly decreases from the outer periphery of the convex surface 415. The convex surface 415 and the emitting portion 412 cooperatively form a smooth, curved and convex surface. A joint of the convex surface 415 of the convex portion 411 and the emitting portion 412 is the vertex of the packaging layer 40.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED), comprising:
an LED die; and
a packaging layer encapsulating the LED die, the packaging layer comprising a top surface and a lateral surface extending downwardly from an outer periphery of the top surface, the top surface defining a convex portion confronting the LED die and an emitting portion surrounding the convex portion, the top surface defining a concave above the convex portion, the lateral surface being ladder-shaped, and having a cross section decreasing downwardly from the top surface.

2. The LED of claim 1, wherein the convex portion extends radially outwardly and upwardly from a center of the top surface of the packaging layer.

3. The LED of claim 1, wherein the emitting portion is planar and annular.

4. The LED of claim 1, wherein the emitting portion is convex, and extends radially outwardly and downwardly from an outer periphery of the convex portion.

5. The LED of claim 1, wherein the lateral surface comprises a plurality of shoulders and a plurality of necks arranged in an alternating fashion, each neck being aslant.

6. The LED of claim 5, wherein each shoulder is planar and annular.

7. The LED of claim 1, wherein the lateral surface is a total reflecting surface coated with reflecting material.

8. The LED of claim 1, wherein the convex portion comprises an inverted cone-shaped surface and a convex surface extending outwardly and upwardly from a top end of the inverted cone-shaped surface, a central axis of the inverted cone-shaped surface being collinear with a central axis of the packaging layer.

9. The LED of claim 8, wherein the emitting portion is convex, and extends radially outwardly and downwardly from the convex portion.

10. A light emitting diode (LED), comprising:
an LED die forming an emitting surface for emitting light generated thereby; and
a packaging layer encapsulating the LED die, the packaging layer comprising an end surface facing the emitting surface of the LED die and a lateral surface extending from an outer periphery of the end surface along an axial direction of the packaging layer, the end surface forming a convex portion confronting the LED die and an emitting portion surrounding the convex portion, light of the LED die traveling to the convex portion being reflected to the lateral surface and then being reflected by the lateral surface to the emitting portion and finally traveling through the emitting portion to an outside.

11. The LED of claim 10, wherein the lateral surface is ladder-shaped and has a diameter gradually decreasing from the end surface along the axial direction of the packaging layer.

12. The LED of claim 10, wherein the convex portion comprises an inverted cone-shaped surface and a convex surface extending outwardly and upwardly from a top end of the inverted cone-shaped surface, the inverted cone-shaped surface being located over the LED die, and a central axis of the inverted cone-shaped surface being collinear with a central axis of the packaging layer.

13. The LED of claim 10, wherein the convex portion extends radially outwardly and upwardly from a center of the end surface of the packaging layer.

14. The LED of claim 10, wherein the emitting portion is convex, and extends radially outwardly and downwardly from an outer periphery of the convex portion.

15. The LED of claim 10, wherein the emitting portion is planar and annular.

16. The LED of claim 10, further comprising a substrate, a pair of inner terminals being formed at an upper side of the substrate and insulated from each other, and a pair of outer terminals being formed at a lower side of the substrate and insulated from each other, a pair of conductive pins extending through the substrate, each conductive pin interconnecting one inner terminal and one outer terminal, the LED die being connected to the inner terminals, the outer terminals being adapted for connecting to a power source to supply current to the LED die.
